(19) United States
(12) Patent Application Publication
(10) Pub. No.: US 2025/0311188 A1
(43) Pub. Date: Oct. 2, 2025

(54) 3D STACKED MEMORY WITH EMBEDDED CAPACITOR

(71) Applicant: Intel Corporation, Santa Clara, CA (US)

(72) Inventors: Abhishek A. Sharma, Portland, OR (US); Wilfred Gomes, Portland, OR (US)

(73) Assignee: Intel Corporation, Santa Clara, CA (US)

(21) Appl. No.: 18/616,763

(22) Filed: Mar. 26, 2024

(51) Int. Cl. H10B 12/00

(52) U.S. Cl. CPC H10B 12/30; H10B 12/03; H10B 12/05

(57) ABSTRACT

A device, such as a memory device, has a semiconductor structure that extends in a direction to an end. The semiconductor structure has a top side extending in the direction and a bottom side extending in the direction, where the bottom side is opposite the top side. The device also has a first conductive structure coupled to the end of the semiconductor structure. The first conductive structure has a top side that is coplanar with the top side of the semiconductor structure. The first conductive structure also has a bottom side that is coplanar with the bottom side of the semiconductor structure. The device also includes a second conductive structure nested within the first conductive structure. A dielectric region is between the first and second conductive structures.

### BACKGROUND

Embedded memory is important to the performance of modern system-on-a-chip (SoC) technology. Low power and high-density embedded memory is used in many different computer products and further improvements are always desirable.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 provides a schematic illustration of an integrated circuit (IC) device with multiple layers of memory that may include three-dimensional (3D) nanoribbon-based dynamic random-access memory (DRAM), according to some embodiments of the present disclosure.

FIG. 2 is a schematic illustration of a one access transistor (1T) and one capacitor (1C) (1T-1C) memory cell, according to some embodiments of the present disclosure.

FIG. 3 is a perspective view of an example 1T-1C memory cell having a nanoribbon-based access transistor, according to some embodiments of the present disclosure.

FIG. 4A-4B are side, cross-sectional views of memory assemblies, according to various embodiments of the present disclosure.

FIG. 5 is a flow diagram of an example process for forming a memory assembly, according to some embodiments of the present disclosure.

FIGS. 6A-6G are side, cross-sectional views of various stages of an example process for forming a memory assembly, according to some embodiments of the present disclosure.

FIGS. 7A and 7B are top views of a wafer and dies that may include one or more memory assemblies in accordance with any of the embodiments disclosed herein.

FIG. 8 is a cross-sectional side view of an IC device that may include one or more memory assemblies in accordance with any of the embodiments disclosed herein.

FIG. 9 is a cross-sectional side view of an IC device assembly that may include one or more memory assemblies in accordance with any of the embodiments disclosed herein.

FIG. 10 is a block diagram of an example computing device that may include one or more memory assemblies in accordance with any of the embodiments disclosed herein.

### DETAILED DESCRIPTION

A DRAM memory cell typically includes a capacitor for storing a bit value, or a memory state (e.g., logical “1” or “0”) of the cell, and an access transistor controlling access to the cell (e.g., access to write information to the cell or access to read information from the cell). Such a memory cell may be referred to as a “1T-1C memory cell,” highlighting the fact that it uses one transistor (i.e., “1T” in the term “1T-1C memory cell”) and one capacitor (i.e., “1C” in the term “1T-1C memory cell”). The capacitor of a 1T-1C memory cell may be coupled to one source/drain (S/D) region/terminal of the access transistor (e.g., to the source region of the access transistor), while the other S/D region of the access transistor may be coupled to a bitline (BL), and a gate terminal of the transistor may be coupled to a wordline (WL). Since such a memory cell can be fabricated with as little as a single access transistor, it can provide higher density and lower standby power versus some other types of memory in the same process technology, e.g., static random-access memory (SRAM).

Various 1T-1C memory cells have, conventionally, been implemented with access transistors being front end-of-line (FEOL), logic-process based, transistors implemented in an upper-most layer of a semiconductor substrate. Conventional FEOL transistors can bring challenges for increasing memory density. One challenge resides in that, given a usable surface area of a substrate, there are only so many FEOL transistors that can be formed in that area, placing a limitation on the density of memory cells incorporating such transistors. In conventional solutions, attempts to increase memory density have included decreasing the critical dimensions of the 1T-1C memory cells, which requires ever-increasing process complexity and cost, resulting in diminishing returns and expected slow pace of memory scaling for future nodes.

Embodiments of the present disclosure may enable increased memory density using a vertically-stacked memory design, where a stack of semiconductor regions are used to provide a stack of DRAM memory cells. In particular, to form a vertically-stacked DRAM assembly, capacitors may be grown in line with in nanoribbons, so that electrodes of the capacitors are reliably aligned and coupled with source or drain (S/D) regions of nanoribbon transistor elements in the memory assembly. An example process may involve providing a stack, the stack including alternating semiconductor structures (e.g., nanoribbon transistor elements) and sacrificial structures. Portions of the sacrificial structures are recessed back from one end of the stack to form a set of first cavities. A dielectric spacer material is deposited in the cavities to form spacers at the end of the stack. Then, portions of the semiconductor structures are recessed back from the end of the stack to form a second set of cavities. Capacitors are grown in the second set of cavities, with the capacitors precisely aligned to the semiconductor structures.

In the context of the present disclosure, the term “above” may refer to being further away from the support structure or the FEOL of an IC device, while the term “below” may refer to being closer towards the support structure or the FEOL of the IC device. Furthermore, as used herein, the term “nanoribbon” refers to a semiconductor structure (e.g., an elongated structure) having a long axis parallel to a support structure (e.g., a substrate, a chip, or a wafer) over which a memory device is provided. In some settings, the term “nanoribbon” has been used to describe a semiconductor structure that has a rectangular transverse cross-section (i.e., a cross-section in a plane perpendicular to the longitudinal axis of the structure), while the term “nanowire” has been used to describe a similar structure but with a circular transverse cross-section. In the present disclosure, the term “nanoribbon” is used to describe both such nanoribbons and such nanowires, as well as semiconductor structures with a longitudinal axis parallel to the support structures and with having transverse cross-sections of any geometry (e.g., oval, or a polygon with rounded corners).

In the following, some descriptions may refer to a particular S/D region or contact being either a source region/contact or a drain region/contact. However, unless specified otherwise, which region/contact of a transistor is considered to be a source region/contact and which region/contact is considered to be a drain region/contact is not important because, as is common in the field of field effect transistors (FETs), designations of source and drain are often interchangeable. Therefore, descriptions of some illustrative embodiments of the source and drain regions/contacts provided herein are applicable to embodiments where the designation of source and drain regions/contacts may be reversed. Furthermore, although descriptions of the present disclosure may refer to logic devices or memory cells provided in a given layer, each layer of the IC devices described herein may also include other types of devices besides logic or memory devices described herein. For example, in some embodiments, IC devices with 3D nanoribbon-based DRAM cells may also include SRAM memory cells, or any other type of memory cells, in any of the layers.

As used herein, the term “metal layer” may refer to a layer above a support structure that includes electrically conductive interconnect structures for providing electrical connectivity between different IC components. Metal layers described herein may also be referred to as “interconnect layers” to clearly indicate that these layers include electrically conductive interconnect structures which may but does not have to be metal.

The systems, methods, and devices of this disclosure each have several innovative aspects, no single one of which is solely responsible for the all of the desirable attributes disclosed herein. Details of one or more implementations of the subject matter described in this specification are set forth in the description below and the accompanying drawings.

In the following detailed description, various aspects of the illustrative implementations may be described using terms commonly employed by those skilled in the art to convey the substance of their work to others skilled in the art. For example, the term “connected” means a direct electrical or magnetic connection between the things that are connected, without any intermediary devices, while the term “coupled” means either a direct electrical or magnetic connection between the things that are connected, or an indirect connection through one or more passive or active intermediary devices. The term “circuit” means one or more passive and/or active components that are arranged to cooperate with one another to provide a desired function. As used herein, a “logic state” (or, alternatively, a “state” or a “bit” value) of a memory cell may refer to one of a finite number of states that the cell can have, e.g., logic states “1” and “0,” each state represented by a different voltage of the capacitor of the cell, while “READ” and “WRITE” memory access or operations refer to, respectively, determining/sensing a logic state of a memory cell and programming/setting a logic state of a memory cell. If used, the terms “oxide,” “carbide,” “nitride,” etc. refer to compounds containing, respectively, oxygen, carbon, nitrogen, etc., the term “high-k dielectric” refers to a material having a higher dielectric constant (k) than silicon oxide, while the term “low-k dielectric” refers to a material having a lower k than silicon oxide. The terms “substantially,” “close,” “approximately,” “near,” and “about,” generally refer to being within +/−20% of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−5-20% of a target value based on the context of a particular value as described herein or as known in the art.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

The description may use the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

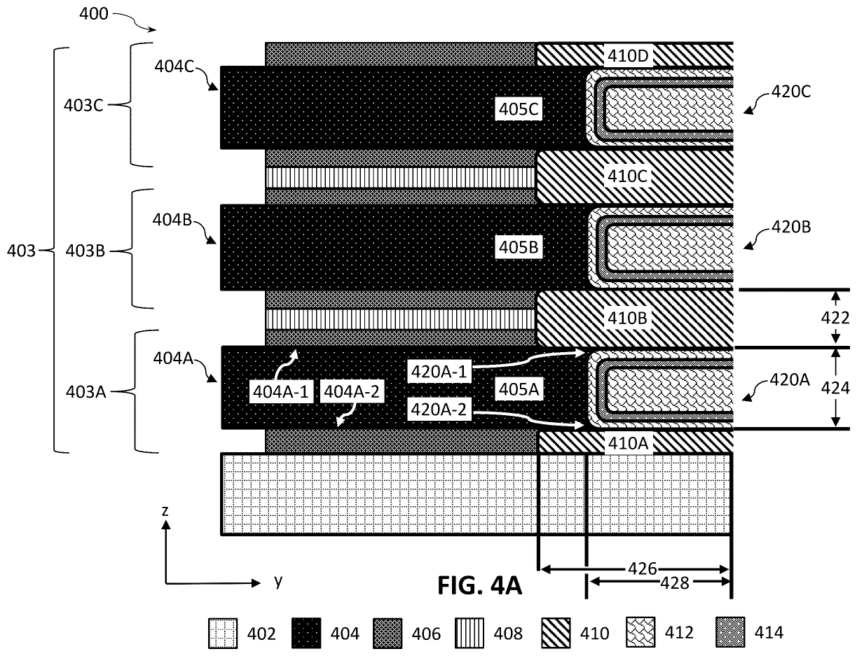

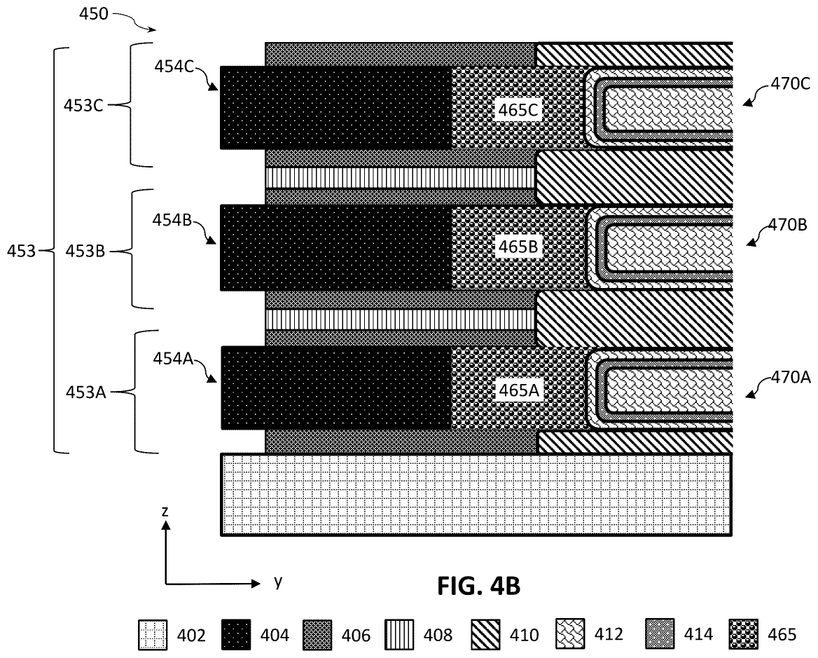

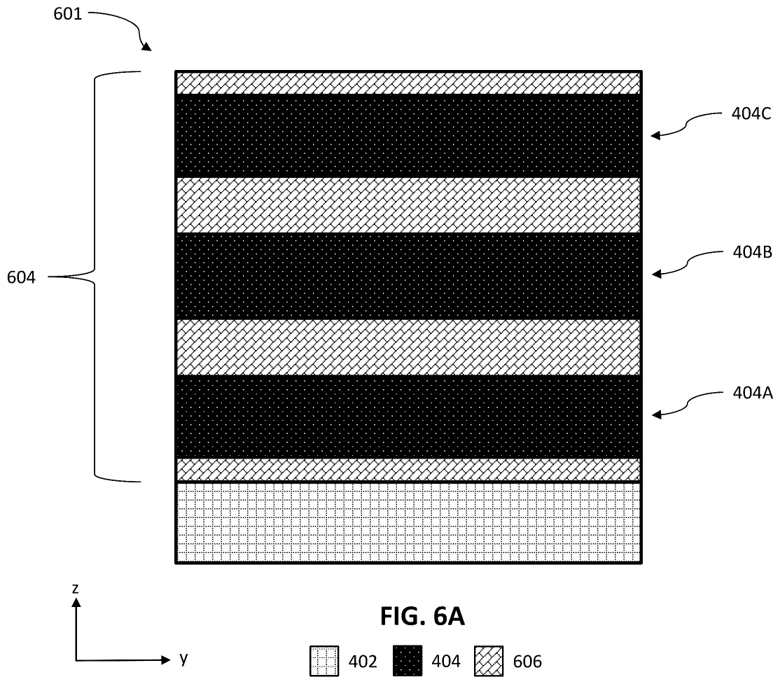

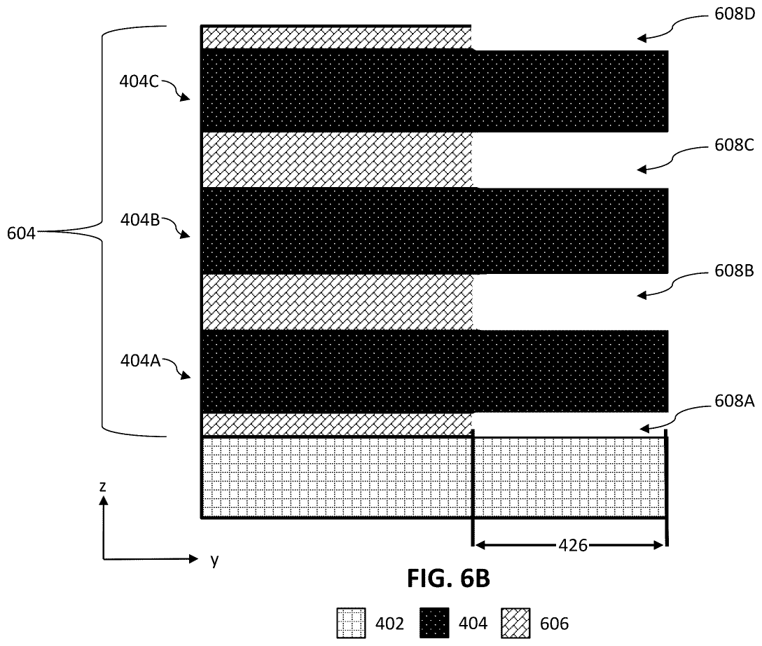

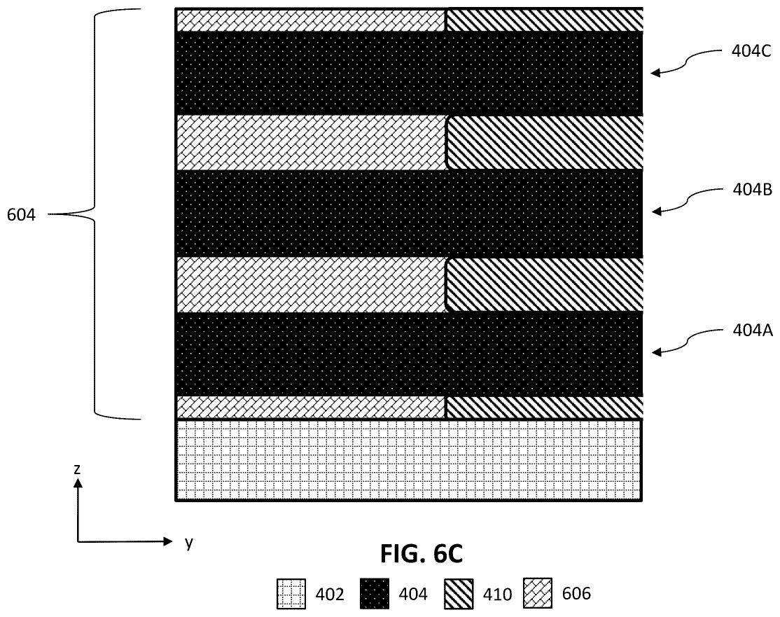

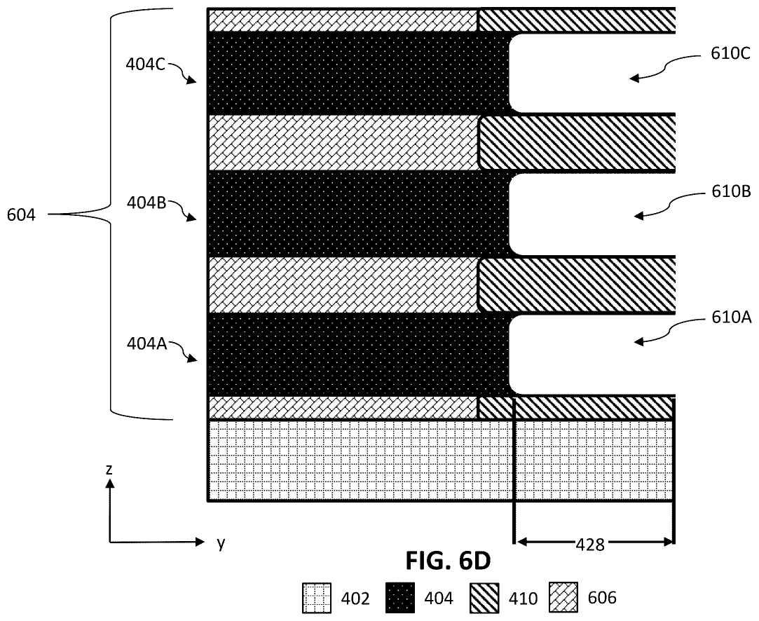

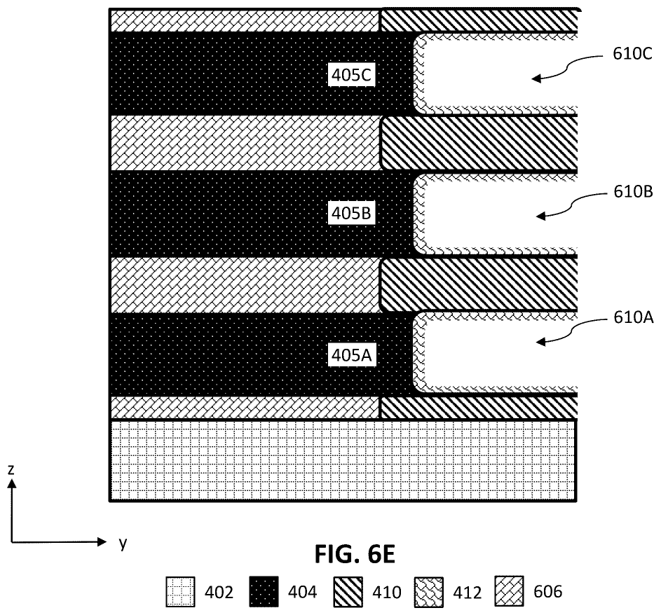

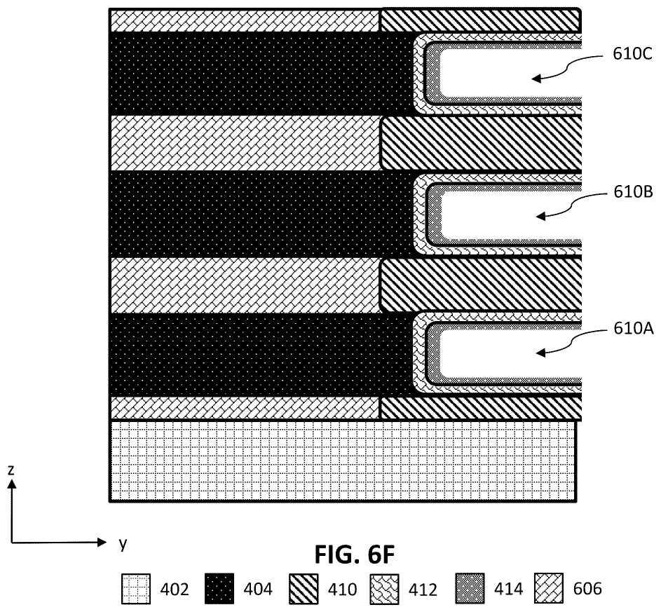

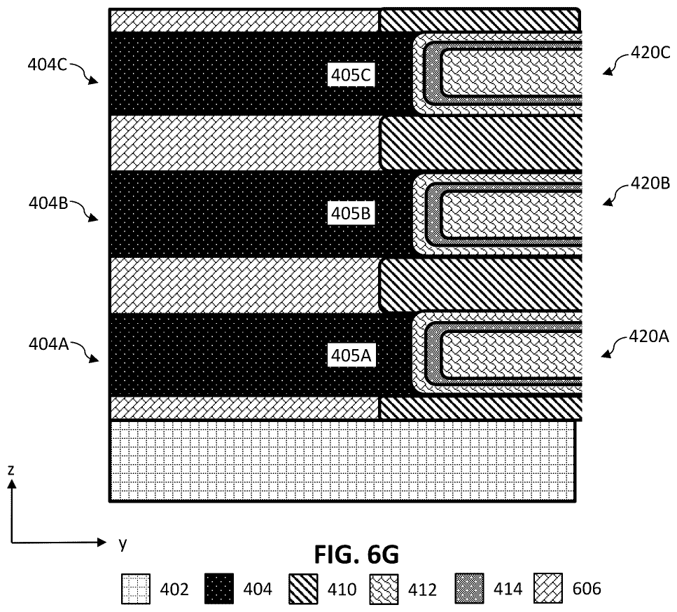

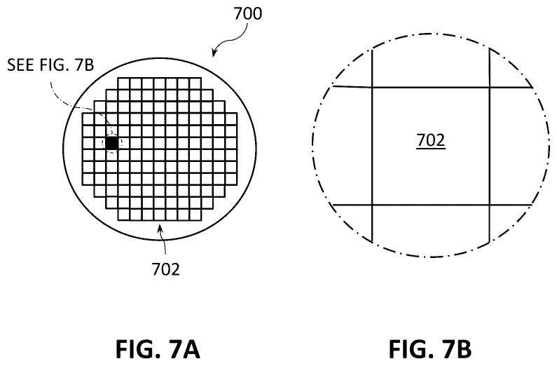

In the following detailed description, reference is made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense. For convenience, if a collection of drawings designated with different letters are present, such as collection may be referred to herein without the letters. For example, the collection of drawings FIGS. 4A-4B may be referred to as “FIG. 4.” As another example, the collection of drawings FIGS. 6A-6G may be referred to as “FIG. 6.” As another example, the collection of drawings FIGS. 7A-7B may be referred to as “FIG. 7.”

In the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication.

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

Various IC devices with 3D nanoribbon-based DRAM cells as described herein may be implemented in, or associated with, one or more components associated with an IC or/and may be implemented between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

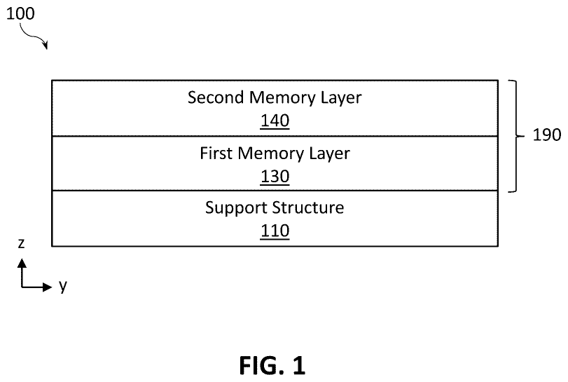

FIG. 1 provides a schematic illustration of a cross-sectional view of an example IC device 100 with multiple layers of memory that may include 3D nanoribbon transistor element-containing DRAM, according to some embodiments of the present disclosure. As shown in FIG. 1, in general, the IC device 100 may include a support structure 110, a first memory layer 130 (e.g., including a first memory assembly or first memory cell), and a second memory layer 140 (e.g., including a second memory assembly or second memory cell).

Implementations of the present disclosure may be formed or carried out on the support structure 110, which may be, e.g., a substrate, a die, a wafer or a chip. The support structure 110 may, e.g., be the wafer 700 of FIG. 7A, discussed below, and may be, or be included in, a die, e.g., the singulated die 702 of FIG. 7B, discussed below. The support structure 110 may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the semiconductor substrate may be non-crystalline. In some embodiments, the support structure 110 may be a printed circuit board (PCB) substrate. Although a few examples of materials from which the substrate may be formed are described here, any material that may serve as a foundation upon which a semiconductor device implementing any of the 3D nanoribbon-based DRAM devices as described herein may be built falls within the spirit and scope of the present disclosure.

The first and second memory layers 130, 140 may, together, be seen as forming a memory assembly 190. Each of the memory layers 130 and 140 may include a set of three-dimensional DRAM cells in a given layer, e.g., the DRAM cells illustrated in FIGS. 4A and 4B. In some embodiments, the memory assembly 190 may include access transistors and capacitors, as well as wordlines (e.g., row selectors), bitlines (e.g., column selectors), and platelines (e.g., joined to electrodes of capacitors in the memory assembly 190), making up memory cells. In other embodiments, the wordlines, bitlines, and platelines may be in a separate layer, e.g., one or more metallization layers formed over the memory assembly 190. For example, the memory assembly 190 and a device region may be formed in different regions over the support structure 110. In some embodiments, the IC device 100 further includes a device region or a device layer. The device region may include devices (e.g., logic transistors) to drive and control a logic IC, and the memory assembly 190 forms an embedded memory utilized by the device region. As another example, if the IC device 100 is a memory device, the device region may form a memory peripheral circuit to control (e.g., access (read/write), store, refresh) memory cells of the memory assembly 190.

In some embodiments, memory assembly 190 and, in some embodiments, a device region, are provided in a FEOL layer. Various metal layers of the back-end-of-line (BEOL) may be used to interconnect various inputs and outputs of the logic devices in the device region or device layer and/or of the memory cells in the memory assembly 190. Generally speaking, each of the metal layers of the BEOL may include a via portion and a trench/interconnect portion. The trench portion of a metal layer is configured for transferring signals and power along electrically conductive (e.g., metal) lines (also sometimes referred to as “trenches”) extending in the x-y plane (e.g., in the x or y directions), while the via portion of a metal layer is configured for transferring signals and power through electrically conductive vias extending in the z-direction, e.g., to any of the adjacent metal layers above or below. Accordingly, vias connect metal structures (e.g., metal lines or vias) from one metal layer to metal structures of an adjacent metal layer. While referred to as “metal” layers, various layers of the BEOL may include only certain patterns of conductive metals, e.g., copper (Cu), aluminum (Al), tungsten (W), or cobalt (Co), or metal alloys of these metals and/or other metals, or more generally, patterns of an electrically conductive material, formed in an insulating medium such as an interlayer dielectric (ILD). The insulating medium may include any suitable ILD materials such as silicon oxide, carbon-doped silicon oxide, silicon carbide, silicon nitride, aluminum oxide, and/or silicon oxynitride.

The illustration of FIG. 1 is intended to provide a general orientation and arrangement of various layers with respect to one another, and, unless specified otherwise in the present disclosure, includes embodiments of the IC device 100 where portions of elements described with respect to one of the layers shown in FIG. 1 may extend into one or more, or be present in, other layers. For example, power and signal interconnects for the various components of the IC device 100 may be present in any of the layers shown in FIG. 1, although not specifically illustrated in FIG. 1. Furthermore, although two memory layers (e.g., first and second memory layers 130, 140) are shown in FIG. 1, in various embodiments, the IC device 100 may include any other number of one or more of such memory layers. For example, the memory assemblies illustrated in FIG. 4A and FIG. 4B include three such memory layers.

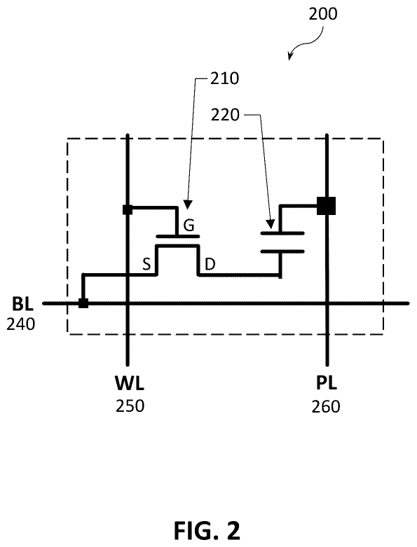

FIG. 2 is a schematic illustration of a memory cell 200 (e.g., a 1T-1C memory cell), according to some embodiments of the present disclosure. The memory cell 200 may be included in the IC device 100 shown in FIG. 1 (for example, in the first memory layer 130 or the second memory layer 140). As shown, the memory cell 200 may include an access transistor 210 and a capacitor 220. The access transistor 210 has a gate terminal, a source terminal, and a drain terminal, indicated in the example of FIG. 2 as terminals G, S, and D, respectively. In the following, the terms “terminal” and “electrode” may be used interchangeably. Furthermore, for S/D terminals, the terms “terminal” and “region” may be used interchangeably.

As shown in FIG. 2, in the memory cell 200, the gate terminal of the access transistor 210 may be coupled to a wordline (WL) 250, one of the S/D terminals of the access transistor 210 may be coupled to a bitline (BL) 240, and the other one of the S/D terminals of the access transistor 210 may be coupled to a first electrode of the capacitor 220. As also shown in FIG. 2, a second electrode of the capacitor 220 may be coupled to a capacitor plateline (PL) 260. As is known in the art, the WL, BL, and PL may be used together to read and program the capacitor 220.

Each of the BL 240, the WL 250, and the PL 260, as well as intermediate elements coupling these lines to various terminals described herein, may be formed of any suitable electrically conductive material, which may include an alloy or a stack of multiple electrically conductive materials. In some embodiments, such electrically conductive materials may include one or more metals or metal alloys, with metals such as ruthenium, palladium, platinum, cobalt, nickel, hafnium, zirconium, titanium, tantalum, and aluminum. In some embodiments, such electrically conductive materials may include one or more electrically conductive alloys oxides or carbides of one or more metals.

As described above, the access transistor 210 may be a nanoribbon-based transistor (or, simply, a nanoribbon transistor, e.g., a nanowire transistor). In a nanoribbon transistor, a gate stack that may include a stack of one or more gate electrode metals and, optionally, a stack of one or more gate dielectrics may be provided around a portion of a semiconductor structure called a “nanoribbon”, forming a gate on all sides of the nanoribbon. The portion of the nanoribbon around which the gate stack wraps around is referred to as a “channel” or a “channel portion.” A semiconductor material of which the channel portion of the nanoribbon is formed is commonly referred to as a “channel material.” A source region and a drain region are provided on the opposite ends of the nanoribbon, on either side of the gate stack, forming, respectively, a source and a drain of such a transistor. Wrap around or gate all-around (GAA) transistors, such as nanoribbon transistors, may provide advantages compared to other transistors having a non-planar architecture, such as fin-shaped transistors (FinFETs).

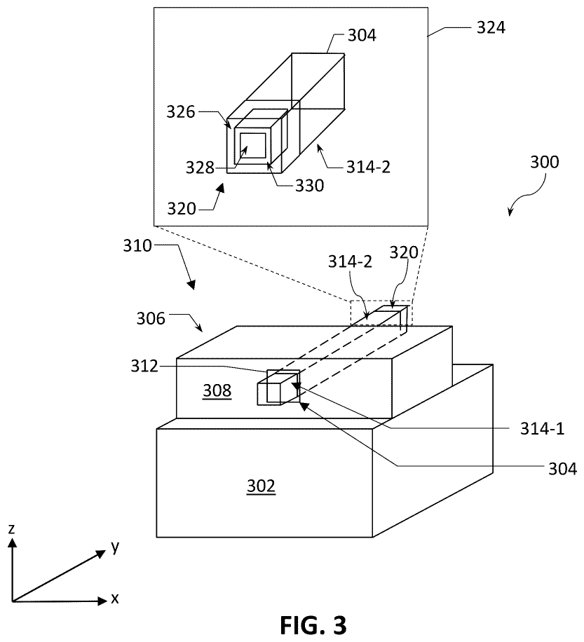

FIG. 3 is a perspective view of a memory cell 300 (e.g., a 1T-1C memory cell), which is an example of the memory cell 200, described above, where the access transistor 210 is implemented as a nanoribbon transistor 310 (e.g., a GAA nanoribbon transistor) including a nanoribbon 304, and where the capacitor 220 is implemented as a capacitor 320, according to some embodiments of the present disclosure. The memory cell 300 is an example of a memory cell that may be included in the memory layer 130 or the memory layer 140.

The arrangement shown in FIG. 3 (and other figures of the present disclosure) is intended to show relative arrangements of some of the components therein, and that the arrangement with the memory cell 300, or portions thereof, may include other components that are not illustrated (e.g., electrical contacts to the source and the drain of the transistor 310, additional layers (such as a spacer layer) around a gate electrode material 308 of the transistor 310, BL, WL, or PL components, etc.). In some embodiments, such an insulator material may be a high-k dielectric including elements such as hafnium, silicon, oxygen, titanium, tantalum, lanthanum, aluminum, zirconium, barium, strontium, yttrium, lead, scandium, niobium, and zinc. Examples of high-k materials that may be used for this purpose may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In other embodiments, the insulator material surrounding portions of the memory cell 300 may be a low-k dielectric material. Some examples of low-k dielectric materials include, but are not limited to, silicon dioxide, carbon-doped oxide, silicon nitride, organic polymers such as perfluorocyclobutane or polytetrafluoroethylene, fused silica glass (FSG), and organosilicates such as silsesquioxane, siloxane, or organosilicate glass.

The transistor 310 includes a channel material formed as a nanoribbon 304 made of one or more semiconductor materials, the nanoribbon 304 provided over a base 302 (e.g., support structure). The base 302 may be the support structure 110, described above.

The nanoribbon 304 may take the form of any nanoribbon structure described herein (such as a semiconductor structure having a rectangular transverse cross-section, or a nanowire, as described above). Although the nanoribbon 304 illustrated in FIG. 3 is shown as having a square cross-section, the nanoribbon 304 may instead have a cross-section that is rectangular but not square, or a cross-section that is rounded at corners or otherwise irregularly shaped. The gate stack 306 may conform to the shape of the nanoribbon 304. The gate stack 306 may form conducting channels on more than three “sides” of the nanoribbon 304, potentially improving performance relative to other transistor architectures, such as FinFETs.

In some embodiments, the channel material of the nanoribbon 304 may be composed of semiconductor material systems including, for example, N-type or P-type materials systems. In some embodiments, the channel material of the nanoribbon 304 may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the channel material of the nanoribbon 304 may include a combination of semiconductor materials. In some embodiments, the channel material of the nanoribbon 304 may include a monocrystalline semiconductor, such as silicon (Si) or germanium (Ge). In some embodiments, the channel material of the nanoribbon 304 may include a compound semiconductor with a first sub-lattice of at least one element from group III of the periodic table (e.g., Al, Ga, In), and a second sub-lattice of at least one element of group V of the periodic table (e.g., P, As, Sb).

For some example N-type transistor embodiments (i.e., for embodiments where the transistor 310 is an n-type metal-oxide-semiconductor (NMOS)), the channel material of the nanoribbon 304 may advantageously include a III-V material having a high electron mobility, such as, but not limited to InGaAs, InP, InSb, and InAs. For some such embodiments, the channel material of the nanoribbon 304 may be a ternary III-V alloy, such as InGaAs, GaAsSb, InAsP, or InPSb. For some InₓGa₁₋₂As fin embodiments, In content (x) may be between 0.6 and 0.9, and may advantageously be at least 0.7 (e.g., In_{0.7}Ga_{0.3}As). In some embodiments with highest mobility, the channel material of the nanoribbon 304 may be an intrinsic III-V material, i.e., a III-V semiconductor material not intentionally doped with any electrically active impurity. In alternate embodiments, a nominal impurity dopant level may be present within the channel material of the nanoribbon 304, for example to further fine-tune a threshold voltage Vt, or to provide halo pocket implants, etc. Even for impurity-doped embodiments however, impurity dopant level within the channel material of the nanoribbon 304 may be relatively low, for example below 10¹⁵ dopant atoms per cubic centimeter (cm³), and advantageously below 10¹³ cm³.

For some example P-type transistor embodiments (i.e., for embodiments where the transistor 310 is a P-type metal-oxide-semiconductor (PMOS)), the channel material of the nanoribbon 304 may advantageously be a group IV material having a high hole mobility, such as, but not limited to Ge or a Ge-rich SiGe alloy. For some example embodiments, the channel material of the nanoribbon 304 may have a Ge content between 0.6 and 0.9, and advantageously may be at least 0.7. In some embodiments with highest mobility, the channel material of the nanoribbon 304 may be intrinsic III-V (or IV for P-type devices) material and not intentionally doped with any electrically active impurity. In alternate embodiments, a nominal impurity dopant level may be present within the channel material of the nanoribbon 304, for example to further set a threshold voltage (Vt), or to provide halo pocket implants, etc. Even for impurity-doped embodiments, however, impurity dopant level within the channel portion may be relatively low, for example below 1015 dopant atoms per cubic centimeter (cm³), and advantageously below 1013 cm³.

In some embodiments, the channel material of the nanoribbon 304 may be a thin-film material, such as a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, if the transistor formed in the nanoribbon is a thin-film transistor (TFT), the channel material of the nanoribbon 304 may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphite, and black phosphorus, each of which may possibly be doped with one or more of gallium, indium, aluminum, fluorine, boron, phosphorus, arsenic, nitrogen, tantalum, tungsten, and magnesium, etc. In some embodiments, the channel material of the nanoribbon 304 may have a thickness between about 5 and 75 nanometers, including all values and ranges therein. In some embodiments, a thin-film channel material may be deposited at relatively low temperatures, which allows depositing the channel material within the thermal budgets imposed on back-end fabrication to avoid damaging other components, e.g., front end components such as logic devices.

The gate stack 306 including the gate electrode material 308 and, optionally, a gate dielectric material 312, may wrap entirely or almost entirely around a portion of the nanoribbon 304 as shown in FIG. 3, with the active region of the channel material of the nanoribbon 304 corresponding to the portion of the nanoribbon 304 wrapped by the gate stack 306. In particular, the gate dielectric material 312 may wrap around a transversal portion of the nanoribbon 304 and the gate electrode material 308 may wrap around the gate dielectric material 312. In some embodiments, the gate stack 306 may fully encircle the nanoribbon 304.

The gate electrode material 308 may include at least one P-type work function metal or N-type work function metal, depending on whether the transistor 310 is a PMOS transistor or an NMOS transistor (a P-type work function metal used as the gate electrode material 308 when the transistor 310 is a PMOS transistor, and an N-type work function metal used as the gate electrode material 308 when the transistor 310 is an NMOS transistor). For a PMOS transistor, metals that may be used for the gate electrode material 308 may include, but are not limited to, ruthenium, palladium, platinum, cobalt, nickel, and conductive metal oxides (e.g., ruthenium oxide). For an NMOS transistor, metals that may be used for the gate electrode material 308 include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrode material 308 may include a stack of two or more metal layers, where one or more metal layers are work function metal layers and at least one metal layer is a fill metal layer. Further layers may be included next to the gate electrode material 308 for other purposes, such as to act as a diffusion barrier layer or/and an adhesion layer.

In some embodiments, the gate dielectric material 312 may include one or more high-k dielectrics including any of the materials discussed herein with reference to the insulator material that may surround portions of the memory cell 300. In some embodiments, an annealing process may be carried out on the gate dielectric material 312 during manufacture of the transistor 310 to improve the quality of the gate dielectric material 312. The gate dielectric material 312 may have a thickness that may, in some embodiments, be between about 0.5 nanometers and 3 nanometers, including all values and ranges therein (e.g., between about 1 and 3 nanometers, or between about 1 and 2 nanometers). In some embodiments, the gate stack 306 may be surrounded by a gate spacer, not shown in FIG. 3. Such a gate spacer may provide separation between the gate stack 306 and source/drain contacts of the transistor 310 and could be made of a low-k dielectric material, some examples of which have been provided above. A gate spacer may include pores or air gaps to further reduce its dielectric constant.

As further shown in FIG. 3, the nanoribbon 304 may include a source region and a drain region on either side of the gate stack 306, thus realizing a transistor. Source and drain regions are formed for the gate stack of each metal-oxide-semiconductor (MOS) transistor. As described above, the source and drain regions of a transistor are interchangeable, and a nomenclature of a first S/D region and a second S/D region of a transistor has been introduced for use in the present disclosure. In FIG. 3, reference numeral 314-1 is used to label the first S/D region and reference numeral 314-2 is used to label the second S/D region of the transistor 310.

The S/D regions 314 (e.g., the first S/D region 314-1 and the second S/D region 314-2) of the transistor 310 may generally be formed using either an implantation/diffusion process or an etching/deposition process. In the former process, dopants such as boron, aluminum, antimony, phosphorous, or arsenic may be ion-implanted into the nanoribbon 304 to form the source and drain regions. An annealing process that activates the dopants and causes them to diffuse further into the nanoribbon 304 may follow the ion implantation process. In the latter process, portions of the nanoribbon 304 may first be etched to form recesses at the locations of future S/D regions. An epitaxial deposition process may then be carried out to fill the recesses with material that is used to fabricate the S/D regions 314. In some implementations, the S/D regions 314 may be fabricated using a silicon alloy such as silicon germanium or silicon carbide. In some implementations, the epitaxially deposited silicon alloy may be doped in situ, with dopants such as boron, arsenic, or phosphorous. In some embodiments, the S/D regions 314 may be formed using one or more alternate semiconductor materials such as germanium or a group III-V material or alloy. In some embodiments, one or more layers of metal and/or metal alloys may be used to form the S/D regions 314.

In some embodiments, the transistor 310 may have a gate length (i.e., a distance between the first and second S/D regions 314 measured along the nanoribbon 304, or a length of the gate stack 306) between about 5 and 40 nanometers, including all values and ranges therein (e.g., between about 22 and 35 nanometers, or between about 20 and 30 nanometers). In some embodiments, an area of a transversal cross-section of the nanoribbon 304 may be between about 25 and 10000 square nanometers, including all values and ranges therein (e.g., between about 25 and 1000 square nanometers, or between about 25 and 500 nanometers). The capacitor 320 is coupled to the transistor 310, and in particular, to the second S/D region 314-2 of the transistor 310. FIG. 3 illustrates that the capacitor 320 may be a non-planar (i.e., three-dimensional) capacitor; in the particular example of FIG. 3, the capacitor 320 is a rectangular prism capacitor. The inset 324 of FIG. 3 illustrates the capacitor 320 in further detail. The orientation of the capacitor 320 in the inset 324 is flipped relative to the orientation in the main illustration of FIG. 3, to more clearly illustrate the first electrode 326 (e.g., first conductive structure), the second electrode 328 (e.g., second conductive structure), and the capacitor dielectric 330 (e.g., dielectric region) of the capacitor 320. The first electrode 326 is an outer electrode, and the second electrode 328 is an inner electrode. The first electrode 326 is around the second electrode 328, with the capacitor dielectric 330 between the first electrode 326 and the second electrode 328.

More specifically, the capacitor dielectric 330 and the second electrode 328 are nested within the first electrode 326, and the second electrode is further nested within the capacitor dielectric 330. At least a portion of the second electrode 328 is surrounded by the first electrode 326, with the capacitor dielectric 330 between the first electrode 326 and the second electrode 328. For example, the second electrode 328 has a first end nearer to the transistor 310 and a second end opposite the first end. The first end of the second electrode 328 is within the first electrode 326. The second end of the second electrode 328 may be outside of the first electrode 326, e.g., extending in a direction away from the transistor 310 a greater distance than the first electrode 326. Said another way, the first electrode 326 may be partially enclosed in the capacitor dielectric 330, and the capacitor dielectric 330 may be partially enclosed in the second electrode 328.

In some embodiments, the capacitor dielectric 330 may include any of the insulator materials described herein, e.g., any of the high-k or low-k dielectric materials described herein. In some embodiments, the capacitor dielectric 330 may be replaced with, or complemented with, a layer of a ferroelectric material (i.e., in some embodiments, a ferroelectric material may be provided between the two electrodes of the capacitor 320 or 220). Such a ferroelectric material may include one or more materials which exhibit sufficient ferroelectric behavior even at thin dimensions. Some examples of such materials known at the moment include hafnium zirconium oxide (HfZrO, also referred to as HZO), silicon-doped (Si-doped) hafnium oxide, germanium-doped (Ge-doped) hafnium oxide, aluminum-doped (Al-doped) hafnium oxide, and yttrium-doped (Y-doped) hafnium oxide. However, in other embodiments, any other materials which exhibit ferroelectric behavior at thin dimensions may be used to replace, or to complement, the capacitor dielectric 330 and are within the scope of the present disclosure. The ferroelectric material included in the capacitor 220/320 may have a thickness that may, in some embodiments, be between about 0.5 nanometers and 10 nanometers, including all values and ranges therein (e.g., between about 1 and 8 nanometers, or between about 0.5 and 5 nanometers). Although not specifically shown in FIG. 3, in some embodiments, the transistor 310 (e.g., the access transistor) may also be a ferroelectric device, i.e., it may have a ferroelectric material, such as any of those described for the capacitor 320. In some embodiments, such a ferroelectric material may be included in the gate stack 306 of the access transistor 210/310, e.g., instead of, or in addition to, the gate dielectric material 312.

In other embodiments (not specifically shown in the figures), the capacitor 320 may be a three-dimensional capacitor having a shape other than a rectangular prism, e.g., a cylindrical capacitor, a hemispherical capacitor, a capacitor shaped similarly to a frustum of a pyramid, and so on. In various embodiments, the shapes of the capacitor 320 may include further modifications, e.g., a rectangular prism may have rounded corners.

Although not specifically shown in FIG. 3, the first S/D region 314-1 may be coupled to a BL, e.g., to the BL 240 of FIG. 2. The gate stack 306 may be coupled to a WL, e.g., to the WL 250 of FIG. 2. The second S/D region 314-2 may be coupled to a first electrode 326 of the capacitor 320, and a second electrode 328 of the capacitor 320 may be coupled to a PL, e.g., to the PL 260 of FIG. 2.

FIG. 4A is a side, cross-sectional view of a memory assembly 400 (or simply, assembly). The memory assembly 400 may include multiple memory cells (e.g., the memory cells 300 as described above), and may be an IC device, or a 3D nanoribbon-based DRAM device, or may be a portion of another memory assembly, a portion of a memory device, a portion of an IC device, or a portion of a 3D nanoribbon-based DRAM device. A legend at the bottom of FIG. 4A illustrates that FIG. 4A uses different patterns to show a support 402, a channel material 404, a gate material 406, a dielectric material 408 (e.g., a gate dielectric material), a spacer material 410, an electrode material 412, and a dielectric material 414 (e.g., an insulator material). Portions of the components shown in FIG. 4A may extend outside of FIG. 4A, or additional components may be outside of FIG. 4A. For example, portions of the channel material 404 may extend outside of FIG. 4A (e.g., past the left side of FIG. 4A). As another example, portions of the electrode material 412 or the dielectric material 414 may extend outside of FIG. 4A (e.g., past the right side of FIG. 4A). As another example, additional memory cells may be present over the support 402 or over a different support in different cross-sections not shown in FIG. 4A (for example, in different cross-sections along the x-axis, extending into the page in FIG. 4A). As another example, one or more BLs not shown in FIG. 4A may be coupled to portions of the channel material 404 (e.g., S/D regions in the channel material 404, past the left side of FIG. 4A), one or more WLs not shown in FIG. 4A may be coupled to portions of the gate material 406, and/or one or more plate lines (PLs) not shown in FIG. 4A may be coupled to portions of the electrode material 412 (e.g., past the right side of FIG. 4A). For ease of illustration, some components may not be illustrated in FIG. 4A. For example, additional gate dielectric or gate spacer material may be present (e.g., adjacent to or proximal to the gate material 406). As another example, more dielectric material may be between or around components of the memory assembly 400 than shown in FIG. 4A.

As shown in FIG. 4A, a stack 403 of memory cells is shown over the support 402, which may be the same as the base 302 described above with reference to FIG. 3. As illustrated, the stack 403 includes three memory cells 403A, 403B, 403C over the support 402. However, this is simply for ease of illustration, and in other embodiments, fewer memory cells (e.g., two) may be included, or additional memory cells may be provided in the stack 403 (e.g., stacked above the memory cell 403C, e.g., past the top side in FIG. 4A) or in other portions of the memory assembly 400.

The memory cells 403A, 403B, 403C include nanoribbons 404A, 404B, 404C (any of which may be the same as the nanoribbon 304 described above with reference to FIG. 3) including the channel material 404 (which may be the same as the channel material of the nanoribbon 304). The nanoribbons 404A, 404B, 404C may be parallel or substantially parallel to one another (e.g. extending substantially along the y-axis as shown in FIG. 4A). The memory cells 403A, 403B, 403C may also include capacitors 420A, 420B, 420C (any of which may be the same as or similar to the capacitor 320 described above with reference to FIG. 3) including the electrode material 412 and the dielectric material 414 (which may be the same as the first and second electrodes 326, 328 and the capacitor dielectric 330 described above with reference to FIG. 3). The nanoribbons 404A, 404B, 404C may include S/D regions 405A, 405B, 405C (which may be the same as the second S/D region 314-2 described above with reference to FIG. 3) that are coupled (e.g., mechanically (e.g., abutting or being adjacent) and/or electrically coupled) to portions of the electrode material 412 closest to the S/D regions 405A, 405B, 405C. Portions of the nanoribbons 404A, 404B, 404C may be coupled to one or more BLs (e.g., not specifically shown in FIG. 4A, but outside of FIG. 4A, e.g., to other S/D regions of the nanoribbons 404A, 404B, 404C past the left side of FIG. 4A), portions of the gate material 406 may be coupled to one or more WLs (not specifically shown in FIG. 4A), and portions of the electrode material 412 (e.g., furthest from the S/D regions 405A, 405B, 405C) may be coupled to one or more PLs (e.g., not specifically shown in FIG. 4A, but outside of FIG. 4A, e.g., past the right side of FIG. 4A).

The nanoribbons 404A, 404B, 404C may be in the gate material 406 (e.g., the gate material 406 may be around the nanoribbons 404A, 404B, 404C). Portions of the gate material 406 may be separated by dielectric material 408, allowing for separated or independent regions of gate material 406 to be around each of the nanoribbons 404A, 404B, 404C, or to allow the gate material 406 to be separated (e.g., physically and/or electrically isolated) from the electrode material 412 or other components of the memory assembly 400. The stack 403 may thus include memory cells 403A, 403B, 403C (which include nanoribbons 404A, 404B, 404C and gate material 406 (e.g., the gate material 406 over or surrounding the nanoribbons 404A, 404B, 404C)) and interstitial layers of dielectric material 408 separating regions of gate material 406. In some embodiments, two or more nanoribbons may share a gate material region.

The spacer material 410 (e.g., shown as a set of four spacers 410A, 410B, 410C, 410D, though in some embodiments, more or fewer spacers may be included) may be adjacent to the gate material 406 and the dielectric material 408 (e.g., to the right of the gate material 406 and dielectric material 408 along the y-axis as shown in FIG. 4A). For example, in FIG. 4A, the spacer 410B is adjacent to gate material 406 and dielectric material 408 to the left of the spacer 410B (e.g., in and/or between memory cells 403A, 403B). The spacer material 410 may be adjacent to the electrode material 412 (e.g., the spacer material 410 may be above or below the capacitors; for example, the spacer 410B between the capacitor 420A and the capacitor 420B, the spacer 410C between the capacitor 420B and the capacitor 420C, etc.).

A region of the spacer material 410 between capacitors (for example, the spacer 410B, between capacitor 420A and capacitor 420B) may have a thickness 422 (e.g., a height along the z-axis as shown in FIG. 4A) of between 3 nm and 150 nm, or between 5 nm and 120 nm, or between 10 nm and 100 nm, or between 20 nm and 70 nm, or any ranges or sub-ranges therebetween. A capacitor between regions of the spacer material 410 (e.g., the capacitor 420A, or the capacitor 420B) may have a thickness 424 (e.g., a height along the z-axis as shown in FIG. 4A, between the regions of spacer material 410) of between 3 nm and 150 nm, or between 5 nm and 120 nm, or between 10 nm and 100 nm, or between 20 nm and 70 nm, or any ranges or sub-ranges therebetween. The thickness 422 and the thickness 424 together may be between 20 nm and 200 nm, or between 40 nm and 180 nm, or between 60 nm and 160 nm, or any ranges or sub-ranges therebetween. The thickness 424 may be substantially the same as or similar to the thickness 422, or the thickness 424 may be greater than or less than the thickness 422.

Regions of the spacer material 410 between capacitors may extend along a length 426 towards the gate material 406 (e.g., towards the left along the y-axis as shown in FIG. 4A). The length 426 may be between 20 nm and 500 nm, or between 50 nm and 300 nm, or between 100 nm and 200 nm, or any ranges or sub-ranges therebetween. Capacitors between regions of the spacer material 410 may extend along a length 428 (e.g., along the y-axis as shown in FIG. 4A) into the stack 403 towards the channel material 404. The length 428 may be smaller than the length 426. For example, the length 428 may be between 10 nm and 50 nm less than the length 426, or between 20 nm and 40 nm less than the length 426, or any ranges or sub-ranges therebetween. The length 428 may be at least 1% lower than the length 426, or at least 2%, at least 3%, at least 5%, at least 10%, at least 20%, or at least 50% lower than the length 426, or any ranges or sub-ranges therebetween.

The spacer material 410 may provide electrical isolation between adjacent capacitors. The spacer material 410 may include a low-k dielectric material or a high-k dielectric material. For example, the spacer material 410 may include a combination of oxygen, silicon, nitrogen, and/or carbon, such as silicon and carbon (e.g., silicon carbide), silicon, carbon, and oxygen (e.g., silicon oxycarbide), silicon and nitrogen (e.g., silicon nitride), or silicon, nitrogen, and oxygen (e.g., silicon oxynitride). In some embodiments, the spacer material 410 may include two or more materials (e.g., a low-k dielectric material and a high-k dielectric material).

The nanoribbons 404A, 404B, 404C (and optionally other nanoribbons not shown) may be aligned (or substantially aligned) with the capacitors 420A, 420B, 420C (and optionally other capacitors not shown) between the gate material 406 and the spacer material 410 (e.g., above and below the nanoribbons 404A, 404B, 404C and capacitors 420A, 420B, 420C). The capacitors 420A, 420B, 420C may be embedded in the stack 403 between the gate material 406 and the spacer material 410, and placed adjacent to the nanoribbons 404A, 404B, 404C. For example, the nanoribbon 404A may have a first surface 404A-1 (e.g., a top surface or top side along the z-axis as shown in FIG. 4A) and a second surface 404A-2 (e.g., a bottom surface or bottom side along the z-axis shown in FIG. 4A) opposite the first surface 404A-1, and the capacitor 420A may have a first surface 420A-1 (e.g., a top surface or top side along the z-axis as shown in FIG. 4A) and a second surface 420A-2 (e.g., a bottom surface or bottom side along the z-axis shown in FIG. 4A) opposite the first surface 420A-1. The first surface 404A-1 may be aligned (e.g., substantially aligned) with the first surface 420A-1 (e.g., the first surface 404A-1 may be at a substantially similar height along the z-axis as the first surface 420A-1, or the first surface 404A-1 may be coplanar or substantially coplanar with the first surface 420A-1), and the second surface 404A-2 may be aligned (e.g., substantially aligned) with the second surface 420A-2 (e.g., the second surface 404A-2 may be at a substantially similar height along the z-axis as the second surface 420A-2, or the second surface 404A-2 may be coplanar or substantially coplanar with the second surface 420A-2). The alignment between the nanoribbons 404A, 404B, 404C and the capacitors 420A, 420B, 420C may be facilitated by the inclusion of the spacer material 410. The spacer material 410 may aid in limiting the placement and orientation of the capacitors 420A, 420B, 420C to positions or locations suitable for alignment with the nanoribbons 404A, 404B, 404C, allowing for reliable coupling between the nanoribbons 404A, 404B, 404C (e.g., the S/D regions 405A, 405B, 405C), and the capacitors 420A, 420B, 420C (e.g., the electrode material 412 closest to the S/D regions 405A, 405B, 405C), as described further below.

Other embodiments are possible. FIG. 4B shows an alternative memory assembly 450. Many of the elements of FIG. 4B (e.g., the support 402, the channel material 404, and so on) are the same as presented above with reference to FIG. 4A, and for convenience, are not discussed again here. In contrast with FIG. 4A, which shows nanoribbons 404A, 404B, 404C where portions of the nanoribbons 404A, 404B, 404C (e.g., portions adjacent to the capacitors 420A, 420B, 420C) include S/D regions 405A, 405B, 405C, FIG. 4B shows that masses of one or more separate S/D materials for the nanoribbon-based transistors may be included adjacent to the nanoribbons (e.g., at ends of the nanoribbons facing capacitors). FIG. 4B shows a stack 453 including memory cells 453A, 453B, 453C, where the memory cells 453A, 453B, 453C include nanoribbons 454A, 454B, 454C. Separate S/D material 465 (e.g., separate from the nanoribbons 454A, 454B, 454C) may be provided. FIG. 4B shows that three masses of separate S/D material 465 may be provided, including mass 465A (adjacent to and/or between the nanoribbon 454A and capacitor 470A), mass 465B (adjacent to and/or between the nanoribbon 454B and capacitor 470B), and mass 465C (adjacent to and/or between the nanoribbon 454C and capacitor 470C).

The masses 465A, 465B, 465C may be may generally be formed using either an implantation/diffusion process or an etching/deposition process. In the former process, dopants such as boron, aluminum, antimony, phosphorous, or arsenic may be ion-implanted into an S/D material precursor to form the S/D material 465. An annealing process that activates the dopants and causes them to diffuse further into the S/D material 465 may follow the ion implantation process. In the latter process, an S/D material precursor may first be etched to form a recess, and an epitaxial deposition process may then be carried out to fill the recess with S/D material 465. In some implementations, the masses 465A, 465B, 465C may be fabricated from a semiconductor material or material alloy using an epitaxy deposition process. The epitaxially deposited semiconductor material or material alloy may be doped in situ, with dopants such as boron, arsenic, or phosphorous.

The S/D material 465 may include one or more narrow bandgap materials (for example, one or more materials having a bandgap that is lower than that of Si, or lower than about 1.1 eV). For example, the S/D material 465 may include germanium or alloys including germanium, indium or alloys including indium (for example, indium and tin, such as InSb), gallium or alloys including gallium (for example, gallium and antimony, such as GaSb), and/or another narrow bandgap material. The use of a narrow bandgap material as or in at least part of the S/D material 465 can aid in reducing electrical resistance, allowing for potentially improved conduction (e.g., reduced barrier to carrier transport) between the nanoribbons 454A, 454B, 454C and the capacitors 470A, 470B, 470C.

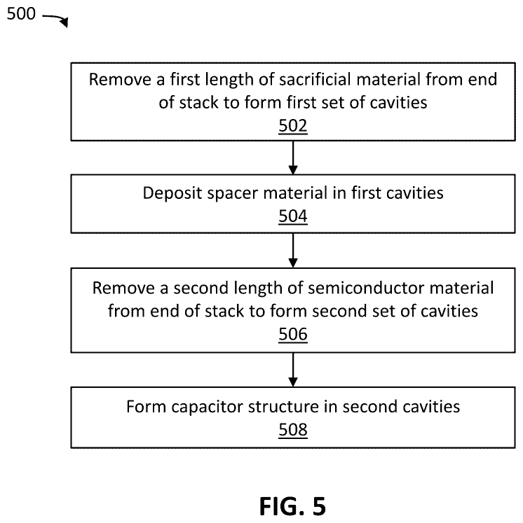

FIG. 5 illustrates one example process 500 that may be used to manufacture a memory assembly (e.g., the memory assembly 400), according to some embodiments of the present disclosure. FIGS. 6A-6G are side, cross-sectional views of various stages in the example process 500. Although the operations discussed below with reference to FIGS. 6A-6G (and others of the accompanying drawings representing manufacturing processes) are illustrated in a particular order, these operations may be performed in any suitable order. Further, additional operations which are not illustrated may also be performed without departing from the scope of the present disclosure. Also, various ones of the operations discussed herein with respect to FIGS. 6A-6G may be modified in accordance with the present disclosure to fabricate others of memory cells, memory assemblies, IC devices, or other devices or assemblies disclosed herein.

At 502 of FIG. 5, a first length of sacrificial material from an end of a stack is removed to form a first set of cavities. FIG. 6A shows an assembly 601 including a support 402 (e.g., which may be the same as the support 402 of FIG. 4A) and a stack 604. The stack may include layers of channel material 404 (which may be the same channel material 404 of FIG. 4A) (e.g., the layers shown as nanoribbons 404A, 404B, 404C) separated by layers of a sacrificial material 606. In this example, three nanoribbons 404A, 404B, 404C are illustrated; in other examples, fewer or additional nanoribbons may be included.

The channel material 404 and sacrificial material 606 may include different materials. In one example, the channel material 404 is silicon, while the sacrificial material 606 includes silicon and germanium. The sacrificial material 606 may be chosen to have a similar crystal structure to the channel material 404, so that monocrystalline layers of the channel material 404 (or substantially monocrystalline layers, e.g., with a grain size of at least 5 nanometers, at least 20 nanometers, at least 50 nanometers, or at least 100 nanometers) and monocrystalline layers of the sacrificial material 606 (or substantially monocrystalline layers) may be formed over each other. In different embodiments, the channel material 404 and/or the sacrificial material 606 may be formed of any suitable single-crystal material, such as sapphire, quartz, silicon, a compound of silicon (e.g., silicon oxide), indium phosphide, germanium or a germanium alloy (e.g., silicon germanium), gallium, arsenic (e.g., an arsenide III compound, where arsenic III is in combination with another element such as boron, aluminum, gallium, or indium), or any group III-V material (i.e., materials from groups III and V of the periodic system of elements). More generally, the channel material 404 may be composed of semiconductor material systems including, for example, N-type or P-type materials systems such as those described for the channel material of the nanoribbon 304 above. In some embodiments, the channel material 404 may include a high mobility oxide semiconductor material, such as tin oxide, antimony oxide, indium oxide, indium tin oxide, titanium oxide, zinc oxide, indium zinc oxide, IGZO, gallium oxide, titanium oxynitride, ruthenium oxide, or tungsten oxide. The channel material 404 may include one or more of cobalt oxide, copper oxide, ruthenium oxide, nickel oxide, niobium oxide, copper peroxide, indium telluride, molybdenite, molybdenum diselenide, tungsten diselenide, tungsten disulfide, molybdenum disulfide, N- or P-type amorphous or polycrystalline silicon, monocrystalline silicon, germanium, indium arsenide, indium gallium arsenide, indium selenide, indium antimonide, zinc antimonide, antimony selenide, silicon germanium, gallium nitride, aluminum gallium nitride, indium phosphite, black phosphorus, zinc sulfide, indium sulfide, gallium sulfide, each of which may possibly be doped with one or more of gallium, indium, aluminum, fluorine, boron, phosphorus, arsenic, nitrogen, tantalum, tungsten, and magnesium, etc. In some embodiments, multiple channel materials may be included, and/or different dopants may be used for the channel material (e.g., channel materials and/or dopants for both NMOS transistors and PMOS transistors).

A cavity etch process may be performed to remove the first length of sacrificial material. The cavity etch process removes a portion of sacrificial material 606 between the nanoribbons 404A, 404B, 404C (e.g., the layers of channel material 404), near the ends of the nanoribbons 404A, 404B, 404C. A selective etch process may be used that removes the sacrificial material while leaving other structures and materials (e.g., the channel material 404 and the support 402) substantially intact. The etch parameters may be tuned to remove only a portion of the sacrificial material 606 (e.g., at the right end of the stack along the y-axis, as shown in FIG. 6A), while leaving the remainder of the sacrificial material 606. The etch process leaves behind cavities. FIG. 6B is a cross-section illustrating the assembly 601 of FIG. 6A after removing a first length 426 of sacrificial material 606 from an end of a stack 604 (e.g., the right end of the stack 604 as shown in FIG. 6B) to form a first set of cavities 608A, 608B, 608C, 608D (or first cavities 608A, 608B, 608C, 608D). The first cavities 608A, 608B, 608C, 608D are formed above, below, and/or between the nanoribbons 404A, 404B, 404C.

At 504 of FIG. 5, spacer material is deposited in the first set of cavities. FIG. 6C shows the assembly of FIG. 6B after the deposition of spacer material 410 in the first cavities 608A, 608B, 608C (shown in FIG. 6B) between nanoribbons 404A, 404B, 404C, and, in this case, above and below the upper and lower most nanoribbons 404C, 404A, respectively. As described above, the spacer material 410 may include a low-k dielectric material and/or a high-k dielectric material. Additionally, as described above, the spacer material 410 may be deposited using a selective deposition process that results in the spacer material 410 being selectively deposited on the sacrificial material 606, while the spacer material 410 is not deposited (or is minimally deposited) along the channel material 404, or the support 402. For example, an area selective deposition (ASD) or area selective atomic layer deposition (AS-ALD) process may be used to deposit the spacer material 410. In an ASD process, the deposition chemistry and/or deposition parameters (e.g., heat and pressure of the deposition chamber) are tuned such that a thin film of spacer material 410 is predominantly deposited on growth areas (here, the sacrificial material 606) and is not predominantly deposited on non-growth areas (here, the channel material 404, or the support 402).

At 506 of FIG. 5, a second length of semiconductor material (e.g., channel material) is removed from an end of the stack to form a second set of cavities. FIG. 6D shows the assembly of FIG. 6C after the removal of channel material 404 from ends of the nanoribbons 404A, 404B, 404C (e.g., at the right side of the stack 604 as shown in FIG. 6D). The removal of a second length 428 of channel material 404 from the nanoribbons 404A, 404B, 404C forms a second set of cavities 610A, 610B, 610C (or second cavities 610A, 610B, 610C). A selective etch process may be used that removes the channel material 404 while leaving other structures and materials (e.g., the spacer material 410 and the support 402) substantially intact. The etch parameters may be tuned to remove only a portion of the channel material 404 (e.g., at the right end of the stack 604), while leaving the remainder of the channel material 404.

At 508 of FIG. 5, capacitors are formed in the second cavities. FIG. 6E shows the assembly of FIG. 6D after deposition of an electrode material 412 in the second cavities 610A, 610B, 610C (shown in FIG. 6D), partially filling the second cavities 610A, 610B, 610C. The electrode material 412 shown in FIG. 6E may form first electrodes of the capacitors as described further below. The electrode material 412 may be deposited using a selective deposition process that results in the electrode material 412 being selectively deposited on the channel material 404, while the electrode material 412 is not deposited (or is minimally deposited) along portions of the spacer material 410 outside of the second cavities 610A, 610B, 610C, or the support 402. The electrode material 412 may be deposited using a conformal deposition process, such as atomic layer deposition (ALD) or chemical vapor deposition (CVD). Conformal deposition generally refers to deposition of a certain coating on an exposed surface of a given structure. During or after the deposition, S/D regions 405A, 405B, 405C of the nanoribbons 404A, 404B, 404C may be coupled (e.g., mechanically and/or electrically coupled) to the electrode material 412.

FIG. 6F shows the assembly of FIG. 6E after deposition of a dielectric material 414 in the second cavities 610A, 610B, 610C. The dielectric material 414 shown in FIG. 6F may form insulators of the capacitors as described further below. The dielectric material 414 may be deposited using a selective deposition process that results in the dielectric material 414 being selectively deposited on the electrode material 412, while the dielectric material 414 is not deposited (or is minimally deposited) along the spacer material 410, or the support 402. The dielectric material 414 may be deposited using a conformal deposition process, such as ALD or CVD.

FIG. 6G shows the assembly of FIG. 6F after deposition of additional electrode material 412 in the second cavities 610A, 610B, 610C (shown in FIG. 6F). The additional electrode material 412 shown in FIG. 6G may form second electrodes of the capacitors as described further below. The additional electrode material 412 may be deposited using a selective deposition process that results in the additional electrode material 412 being selectively deposited on the dielectric material 414, while the additional electrode material 412 is not deposited (or is minimally deposited) along the spacer material 410, or the support 402. The additional electrode material 412 may be deposited using a conformal deposition process, such as ALD or CVD. The portions of the electrode material 412, as noted above, may form first and second electrodes of capacitors, and the dielectric material 414 may form insulators of capacitors. Thus, capacitors 420A, 420B, 420C are formed.

Additional processes may be performed on the assembly shown in FIG. 6G to manufacture a memory assembly. For example, a gate stack may be formed in the assembly. The remaining portion of the sacrificial material 606 between or around the nanoribbons 404A, 404B, 404C may be removed, e.g., using an etching process. After removal of the sacrificial material 606, gate material (e.g., the gate material 406 described above with reference to FIG. 4A) may be grown around the nanoribbons 404A, 404B, 404C, and additional materials may be placed (e.g., the dielectric material 408, or other materials (such as other metals, conductive materials, or dielectric materials)), forming the gate stack. The gate stack may be coupled to one or more WLs. Multiple gate materials may be grown in layers, e.g., a layers of dielectric and layers of conductive material forming gate electrodes. As another example, additional S/D regions (on other portions of the nanoribbons 404A, 404B, 404C than the S/D regions 405A, 405B, 405C) may be coupled to BLs, and electrode material 412 (e.g., the additional electrode material 412 forming second electrodes of the capacitors 420A, 420B, 420C) may be coupled to PLs, the nanoribbons 404A, 404B, 404C and capacitors 420A, 420B, 420C after coupling to the BLs, WL, and PLs operating as 1T-1C 3D DRAM memory cells. Other processes in addition to the ones described above may be performed to form various memory cells, memory assemblies, or other devices (e.g., IC devices).

Arrangements with one or more 3D nanoribbon-based DRAM devices as disclosed herein may be included in any suitable electronic device. FIGS. 7-10 illustrate various examples of devices and components that may include one or more three-dimensional memory arrays as disclosed herein.

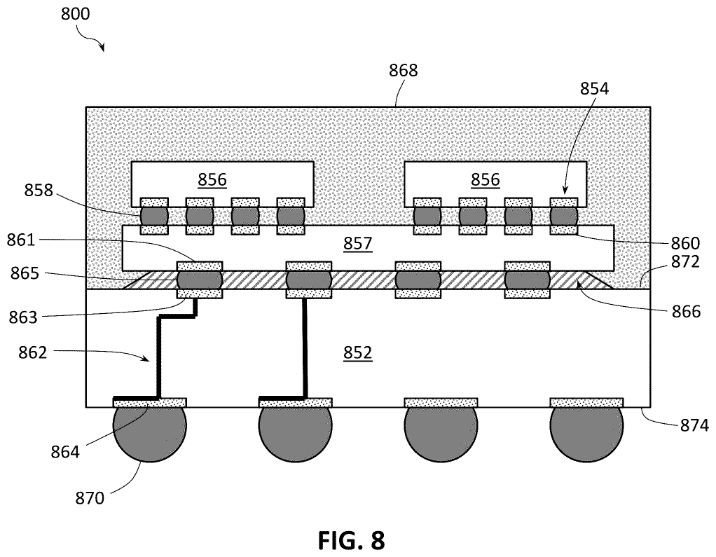

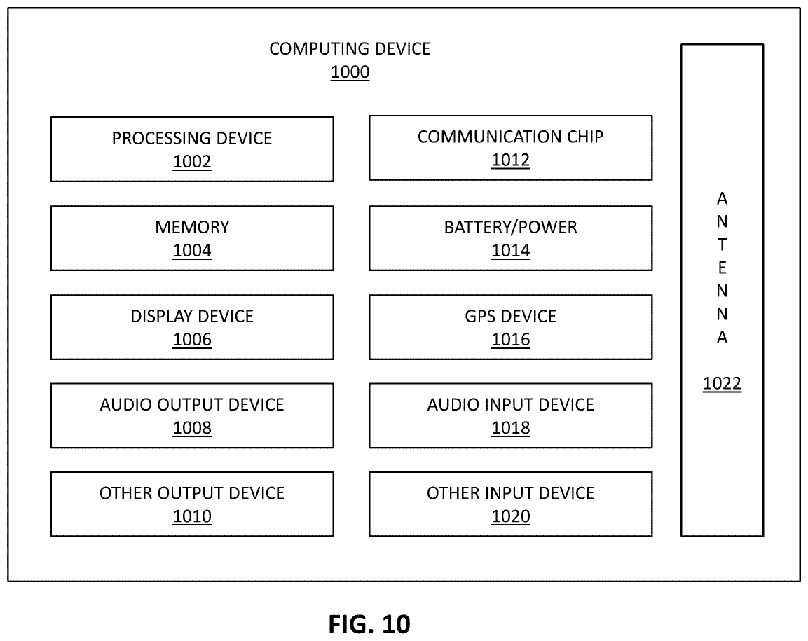

FIGS. 7A-7B are top views of a wafer 700 and dies 702 that may include one or more 3D nanoribbon-based DRAM devices in accordance with any of the embodiments disclosed herein. In some embodiments, the dies 702 may be included in an IC package, in accordance with any of the embodiments disclosed herein. For example, any of the dies 702 may serve as any of the dies 856 in an IC package 800 shown in FIG. 8. The wafer 700 may be composed of semiconductor material and may include one or more dies 702 having IC structures formed on a surface of the wafer 700. Each of the dies 702 may be a repeating unit of a semiconductor product that includes any suitable IC (e.g., ICs including one or more memory arrays with 3D nanoribbon-based DRAM devices as described herein). After the fabrication of the semiconductor product is complete (e.g., after manufacture of one or more layers of the nanoribbon-based DRAM cells as described herein (e.g. any embodiment of the memory assembly 190 of the IC device 100, e.g. including an array of any of the memory cells described herein)), the wafer 700 may undergo a singulation process in which each of the dies 702 is separated from one another to provide discrete “chips” of the semiconductor product. In particular, devices that include one or more 3D nanoribbon-based DRAM devices as disclosed herein may take the form of the wafer 700 (e.g., not singulated) or the form of the die 702 (e.g., singulated). The die 702 may include supporting circuitry to route electrical signals to various memory cells, transistors, capacitors, as well as any other IC components. In some embodiments, the wafer 700 or the die 702 may implement or include a memory device (e.g., a DRAM device), a logic device (e.g., an AND, OR, NAND, or NOR gate), or any other suitable circuit element. Multiple ones of these devices may be combined on a single die 702. For example, a memory array formed by multiple memory devices may be formed on a same die 702 as a processing device (e.g., the processing device 1002 of FIG. 10) or other logic that is configured to store information in the memory devices or execute instructions stored in the memory array.

FIG. 8 is a side, cross-sectional view of an example IC package 800 that may include one or more 3D nanoribbon-based DRAM devices in accordance with any of the embodiments disclosed herein. In some embodiments, the IC package 800 may be a system-in-package (SiP).

The package substrate 852 may be formed of a dielectric material (e.g., a ceramic, a buildup film, an epoxy film having filler particles therein, etc.), and may have conductive pathways extending through the dielectric material between the face 872 and the face 874, or between different locations on the face 872, and/or between different locations on the face 874.

The package substrate 852 may include conductive contacts 863 that are coupled to conductive pathways 862 through the package substrate 852, allowing circuitry within the dies 856 and/or the interposer 857 to electrically couple to various ones of the conductive contacts 864 (or to other devices included in the package substrate 852, not shown).

The IC package 800 may include an interposer 857 coupled to the package substrate 852 via conductive contacts 861 of the interposer 857, first-level interconnects 865, and the conductive contacts 863 of the package substrate 852. The first-level interconnects 865 illustrated in FIG. 8 are solder bumps, but any suitable first-level interconnects 865 may be used. In some embodiments, no interposer 857 may be included in the IC package 800; instead, the dies 856 may be coupled directly to the conductive contacts 863 at the face 872 by first-level interconnects 865.

The IC package 800 may include one or more dies 856 coupled to the interposer 857 via conductive contacts 854 of the dies 856, first-level interconnects 858, and conductive contacts 860 of the interposer 857. The conductive contacts 860 may be coupled to conductive pathways (not shown) through the interposer 857, allowing circuitry within the dies 856 to electrically couple to various ones of the conductive contacts 861 (or to other devices included in the interposer 857, not shown). The first-level interconnects 858 illustrated in FIG. 8 are solder bumps, but any suitable first-level interconnects 858 may be used. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

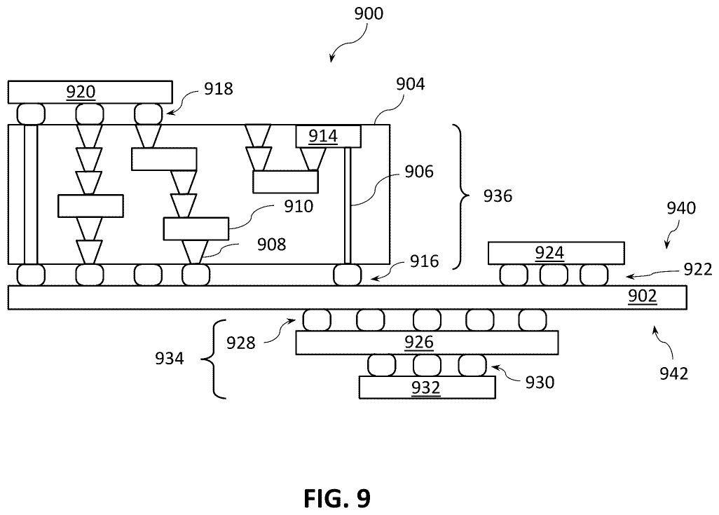

In some embodiments, an underfill material 866 may be disposed between the package substrate 852 and the interposer 857 around the first-level interconnects 865, and a mold compound 868 may be disposed around the dies 856 and the interposer 857 and in contact with the package substrate 852. In some embodiments, the underfill material 866 may be the same as the mold compound 868. Example materials that may be used for the underfill material 866 and the mold compound 868 are epoxy mold materials, as suitable. Second-level interconnects 870 may be coupled to the conductive contacts 864. The second-level interconnects 870 illustrated in FIG. 8 are solder balls (e.g., for a ball grid array arrangement), but any suitable second-level interconnects 870 may be used (e.g., pins in a pin grid array arrangement or lands in a land grid array arrangement). The second-level interconnects 870 may be used to couple the IC package 800 to another component, such as a circuit board (e.g., a motherboard), an interposer, or another IC package, as known in the art and as discussed below with reference to FIG. 9.

The dies 856 may take the form of any of the embodiments of dies (such as the die 702 discussed herein, which may include any of the embodiments of the 3D nanoribbon-based DRAM devices as described herein). In embodiments in which the IC package 800 includes multiple dies 856, the IC package 800 may be referred to as a multi-chip package (MCP). The dies 856 may include circuitry to perform any desired functionality. For example, one or more of the dies 856 may be logic dies (e.g., silicon-based dies), and one or more of the dies 856 may be memory dies (e.g., high bandwidth memory), including embedded memory dies as described herein. In some embodiments, any of the dies 856 may include one or more 3D nanoribbon-based DRAM devices, e.g., as discussed above; in some embodiments, at least some of the dies 856 may not include any 3D nanoribbon-based DRAM devices.

The IC package 800 illustrated in FIG. 8 may be a flip chip package, although other package architectures may be used. For example, the IC package 800 may be a ball grid array (BGA) package, such as an embedded wafer-level ball grid array (eWLB) package. In another example, the IC package 800 may be a wafer-level chip scale package (WLCSP) or a panel fan-out (FO) package. Although two dies 856 are illustrated in the IC package 800 of FIG. 8, an IC package 800 may include any desired number of the dies 856. An IC package 800 may include additional passive components, such as surface-mount resistors, capacitors, and inductors disposed on the first face 872 or the second face 874 of the package substrate 852, or on either face of the interposer 857. More generally, an IC package 800 may include any other active or passive components known in the art.

FIG. 9 is a cross-sectional side view of an IC device assembly 900 that may include components having one or more 3D nanoribbon-based DRAM devices in accordance with any of the embodiments disclosed herein. The IC device assembly 900 includes a number of components disposed on a circuit board 902 (which may be, e.g., a motherboard). The IC device assembly 900 includes components disposed on a first face 940 of the circuit board 902 and an opposing second face 942 of the circuit board 902; generally, components may be disposed on one or both faces 940 and 942. In particular, any suitable ones of the components of the IC device assembly 900 may include any of one or more 3D memory arrays with nanoribbon-based DRAM cells in accordance with any of the embodiments disclosed herein; e.g., any of the IC packages discussed below with reference to the IC device assembly 900 may take the form of any of the embodiments of the IC package 800 discussed above with reference to FIG. 8 (e.g., may include one or more 3D nanoribbon-based DRAM devices provided on or in a die 856).

In some embodiments, the circuit board 902 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 902. In other embodiments, the circuit board 902 may be a non-PCB substrate.

The IC device assembly 900 illustrated in FIG. 9 includes a package-on-interposer structure 936 coupled to the first face 940 of the circuit board 902 by coupling components 916. The coupling components 916 may electrically and mechanically couple the package-on-interposer structure 936 to the circuit board 902, and may include solder balls (e.g., as shown in FIG. 8), male and female portions of a socket, an adhesive, an underfill material, and/or any other suitable electrical and/or mechanical coupling structure.

The package-on-interposer structure 936 may include an IC package 920 coupled to an interposer 904 by coupling components 918. The coupling components 918 may take any suitable form for the application, such as the forms discussed above with reference to the coupling components 916. The IC package 920 may be or include, for example, a die (the die 702 of FIG. 7B), an IC device, or any other suitable component. In particular, the IC package 920 may include one or more 3D nanoribbon-based DRAM devices as described herein. Although a single IC package 920 is shown in FIG. 7, multiple IC packages may be coupled to the interposer 904; indeed, additional interposers may be coupled to the interposer 904. The interposer 904 may provide an intervening substrate used to bridge the circuit board 902 and the IC package 920. Generally, the interposer 904 may spread a connection to a wider pitch or reroute a connection to a different connection. For example, the interposer 904 may couple the IC package 920 (e.g., a die) to a BGA of the coupling components 916 for coupling to the circuit board 902. In the embodiment illustrated in FIG. 9, the IC package 920 and the circuit board 902 are attached to opposing sides of the interposer 904; in other embodiments, the IC package 920 and the circuit board 902 may be attached to a same side of the interposer 904. In some embodiments, three or more components may be interconnected by way of the interposer 904.

The interposer 904 may be formed of an epoxy resin, a fiberglass-reinforced epoxy resin, a ceramic material, or a polymer material such as polyimide. In some implementations, the interposer 904 may be formed of alternate rigid or flexible materials that may include the same materials described above for use in a semiconductor substrate, such as silicon, germanium, and other group III-V and group IV materials. The interposer 904 may include metal interconnects 908 and vias 910, including but not limited to through-silicon vias (TSVs) 906. The interposer 904 may further include embedded devices 914, including both passive and active devices. Such devices may include, but are not limited to, capacitors, decoupling capacitors, resistors, inductors, fuses, diodes, transformers, sensors, electrostatic discharge (ESD) protection devices, and memory devices. More complex devices such as radio frequency (RF) devices, power amplifiers, power management devices, antennas, arrays, sensors, and microelectromechanical systems (MEMS) devices may also be formed on the interposer 904. The package-on-interposer structure 936 may take the form of any of the package-on-interposer structures known in the art.

The IC device assembly 900 may include an IC package 924 coupled to the first face 940 of the circuit board 902 by coupling components 922. The coupling components 922 may take the form of any of the embodiments discussed above with reference to the coupling components 916, and the IC package 924 may take the form of any of the embodiments discussed above with reference to the IC package 920.

The IC device assembly 900 illustrated in FIG. 9 includes a package-on-package structure 934 coupled to the second face 942 of the circuit board 902 by coupling components 928. The package-on-package structure 934 may include an IC package 926 and an IC package 932 coupled together by coupling components 930 such that the IC package 926 is disposed between the circuit board 902 and the IC package 932. The coupling components 928 and 930 may take the form of any of the embodiments of the coupling components 916 discussed above, and the IC packages 926 and 932 may take the form of any of the embodiments of the IC package 920 discussed above. The package-on-package structure 934 may be configured in accordance with any of the package-on-package structures known in the art.

FIG. 10 is a block diagram of an example computing device 1000 that may include one or more components with one or more 3D nanoribbon-based DRAM devices in accordance with any of the embodiments disclosed herein. For example, any suitable ones of the components of the computing device 1000 may include a die (e.g., the die 702 (FIG. 7B)) including one or more 3D arrays of nanoribbon-based DRAM cells in accordance with any of the embodiments disclosed herein. Any of the components of the computing device 1000 may include an IC package 800 (FIG. 8). Any of the components of the computing device 1000 may include an IC device assembly 900 (FIG. 9).

A number of components are illustrated in FIG. 10 as included in the computing device 1000, but any one or more of these components may be omitted or duplicated, as suitable for the application. In some embodiments, some or all of the components included in the computing device 1000 may be attached to one or more motherboards. In some embodiments, some or all of these components are fabricated onto a single SoC die.

Additionally, in various embodiments, the computing device 1000 may not include one or more of the components illustrated in FIG. 10, but the computing device 1000 may include interface circuitry for coupling to the one or more components. For example, the computing device 1000 may not include a display device 1006, but may include display device interface circuitry (e.g., a connector and driver circuitry) to which a display device 1006 may be coupled. In another set of examples, the computing device 1000 may not include an audio input device 1018 or an audio output device 1008, but may include audio input or output device interface circuitry (e.g., connectors and supporting circuitry) to which an audio input device 1018 or audio output device 1008 may be coupled.

The computing device 1000 may include a processing device 1002 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1002 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices. The computing device 1000 may include a memory 1004, which may itself include one or more memory devices such as volatile memory (e.g., DRAM), nonvolatile memory (e.g., read-only memory (ROM)), flash memory, solid state memory, and/or a hard drive. In some embodiments, the memory 1004 may include memory that shares a die with the processing device 1002. This memory may be used as cache memory and may include eDRAM, e.g., a 3D array of nanoribbon-based DRAM cells as described herein, and/or spin transfer torque magnetic random-access memory (STT-MRAM).

In some embodiments, the computing device 1000 may include a communication chip 1012 (e.g., one or more communication chips). For example, the communication chip 1012 may be configured for managing wireless communications for the transfer of data to and from the computing device 1000. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1012 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1012 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1012 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1012 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1012 may operate in accordance with other wireless protocols in other embodiments. The computing device 1000 may include an antenna 1022 to facilitate wireless communications and/or to receive other wireless communications (such as AM or FM radio transmissions).

In some embodiments, the communication chip 1012 may manage wired communications, such as electrical, optical, or any other suitable communication protocols (e.g., the Ethernet). As noted above, the communication chip 1012 may include multiple communication chips. For instance, a first communication chip 1012 may be dedicated to shorter-range wireless communications such as Wi-Fi or Bluetooth, and a second communication chip 1012 may be dedicated to longer-range wireless communications such as global positioning system (GPS), EDGE, GPRS, CDMA, WiMAX, LTE, EV-DO, or others. In some embodiments, a first communication chip 1012 may be dedicated to wireless communications, and a second communication chip 1012 may be dedicated to wired communications.

The computing device 1000 may include battery/power circuitry 1014. The battery/power circuitry 1014 may include one or more energy storage devices (e.g., batteries or capacitors) and/or circuitry for coupling components of the computing device 1000 to an energy source separate from the computing device 1000 (e.g., AC line power).

The computing device 1000 may include a display device 1006 (or corresponding interface circuitry, as discussed above). The display device 1006 may include any visual indicators, such as a heads-up display, a computer monitor, a projector, a touchscreen display, a liquid crystal display (LCD), a light-emitting diode display, or a flat panel display, for example.

The computing device 1000 may include an audio output device 1008 (or corresponding interface circuitry, as discussed above). The audio output device 1008 may include any device that generates an audible indicator, such as speakers, headsets, or earbuds, for example.

The computing device 1000 may include an audio input device 1018 (or corresponding interface circuitry, as discussed above). The audio input device 1018 may include any device that generates a signal representative of a sound, such as microphones, microphone arrays, or digital instruments (e.g., instruments having a musical instrument digital interface (MIDI) output).

The computing device 1000 may include a GPS device 1016 (or corresponding interface circuitry, as discussed above). The GPS device 1016 may be in communication with a satellite-based system and may receive a location of the computing device 1000, as known in the art.

The computing device 1000 may include an other output device 1010 (or corresponding interface circuitry, as discussed above). Examples of the other output device 1010 may include an audio codec, a video codec, a printer, a wired or wireless transmitter for providing information to other devices, or an additional storage device.

The computing device 1000 may include an other input device 1020 (or corresponding interface circuitry, as discussed above). Examples of the other input device 1020 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 1000 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 1000 may be any other electronic device that processes data.

The following paragraphs provide various examples of the embodiments disclosed herein.

Example 1 provides a device including a semiconductor structure that extends in a direction to an end, where the semiconductor structure has a top side extending in the direction and a bottom side extending in the direction, the bottom side opposite the top side; a first conductive structure coupled to the end of the semiconductor structure, where the first conductive structure has a top side that is coplanar with the top side of the semiconductor structure, and the first conductive structure has a bottom side that is coplanar with the bottom side of the semiconductor structure; a second conductive structure nested within the first conductive structure; and a dielectric region between the first conductive structure and the second conductive structure.

Example 2 provides the device of example 1, where an end of the first conductive structure is along the end of the semiconductor structure.

Example 3 provides the device of examples 1 or 2, further including a third conductive structure over the semiconductor structure, the third conductive structure separated from the first conductive structure.

Example 4 provides the device of example 3, where the semiconductor structure has a first length in the direction, and the third conductive structure has a second length in the direction, the second length less than the first length.

Example 5 provides the device of examples 3 or 4, where the third conductive structure is around the semiconductor structure.

Example 6 provides the device of any one of examples 3-5, further including a spacer adjacent to the third conductive structure.

Example 7 provides the device of example 6, where the spacer is over a portion of the semiconductor structure.

Example 8 provides the device of examples 6 or 7, where the spacer is over at least a portion of the first conductive structure.

Example 9 provides the device of any one of examples 3-8, where the semiconductor structure is a first semiconductor structure, and the device further includes a second semiconductor structure, the third conductive structure between the first semiconductor structure and the second semiconductor structure.

Example 10 provides the device of example 9, where the direction is a first direction, and the first semiconductor structure and the second semiconductor structure are arranged in a stack along a second direction substantially perpendicular to the first direction.

Example 11 provides the device of example 3, further including a spacer adjacent to the third conductive structure, where the direction is a first direction, the end is a first end, the spacer extends in a second direction substantially opposed to the first direction to a second end, and the first conductive structure extends in the second direction to a third end, the second end further along the second direction than the third end.

Example 12 provides the device of any of examples 1-11, where the second conductive structure is at least partially enclosed in the dielectric region, and the dielectric region is at least partially enclosed in the first conductive structure.

Example 13 provides a device, including a support structure; a first nanoribbon and a second nanoribbon arranged in a stack over the support structure, the second nanoribbon extending in a first direction parallel to the first nanoribbon in the stack, the first nanoribbon having a first end along the first direction, the first nanoribbon having a first top extending in the first direction and a first bottom extending in the first direction; and a capacitor structure adjacent to the first nanoribbon, the capacitor structure extending in the first direction from the first end of the first nanoribbon to a second end, where the capacitor structure has a second top extending in the first direction and a second bottom extending in the first direction, the first top and the second top are aligned, and the first bottom and the second bottom are aligned.

Example 14 provides the device of example 13, where the first nanoribbon is coupled to the capacitor structure.

Example 15 provides the device of examples 13 or 14, where the capacitor structure includes a first electrode structure having a first height between the second bottom and the second top, a second electrode structure nested within the first electrode structure, the second electrode structure having a second height that is less than the first height.

Example 16 provides the device of any one of examples 13-15, where the capacitor structure is a first capacitor structure, and the device further includes a second capacitor structure adjacent to the second nanoribbon, the second capacitor structure having a top and a bottom aligned to a top and a bottom of the second nanoribbon.

Example 17 provides the device of any one of examples 13-16, further including a gate region between the first nanoribbon and the second nanoribbon.

Example 18 provides the device of example 17, further including a spacer between the first nanoribbon and the second nanoribbon, the spacer adjacent to the gate region.

Example 19 provides a method including providing a stack of first structures of a first material with second structures of a second material in between adjacent ones of the first structures, the stack having an end; etching portions of the first structures from the end to form a plurality of cavities in the first structures at the end; depositing a layer of a conductive material within the plurality of cavities.

Example 20 provides the method of example 19, further including depositing a layer of a dielectric material within the plurality of cavities over the conductive material.

Example 21 provides the method of example 20, further including depositing a second layer of the conductive material in the plurality of cavities over the dielectric material.

Example 22 provides the method of any one of examples 19-21, where the plurality of cavities is a first plurality of cavities, further including etching portions of the second structures from the end to form a second plurality of cavities in the second structures at the end, and depositing a spacer material in the second plurality of cavities in the second structures.

Example 23 provides the method of example 22, where a first cavity of the first plurality of cavities extends a first distance from the end into one of the first structures, a second cavity of the second plurality of cavities extends a second distance from the end into one of the second structures, and the second distance is greater than the first distance.

Example 24 provides the method of any one of examples 19-23, further including replacing the second structures with one or more third structures.

1. A device comprising:
a semiconductor structure that extends in a direction to an end, wherein the semiconductor structure has a top side extending in the direction and a bottom side extending in the direction, the bottom side opposite the top side;
a first conductive structure coupled to the end of the semiconductor structure, wherein the first conductive structure has a top side that is coplanar with the top side of the semiconductor structure, and the first conductive structure has a bottom side that is coplanar with the bottom side of the semiconductor structure;
a second conductive structure nested within the first conductive structure; and
a dielectric region between the first conductive structure and the second conductive structure.

2. The device of claim 1, further comprising a third conductive structure over the semiconductor structure, the third conductive structure separated from the first conductive structure.

3. The device of claim 2, wherein the semiconductor structure has a first length in the direction, and the third conductive structure has a second length in the direction, the second length less than the first length.

4. The device of claim 2, wherein the third conductive structure is around the semiconductor structure.

5. The device of claim 2, further comprising a spacer adjacent to the third conductive structure.

6. The device of claim 5, wherein the spacer is over a portion of the semiconductor structure.

7. The device of claim 5, wherein the spacer is over at least a portion of the first conductive structure.

8. The device of claim 2, wherein the semiconductor structure is a first semiconductor structure, and the device further comprises a second semiconductor structure, the third conductive structure between the first semiconductor structure and the second semiconductor structure.

9. The device of claim 8, wherein the direction is a first direction, and the first semiconductor structure and the second semiconductor structure are arranged in a stack along a second direction substantially perpendicular to the first direction.

10. The device of claim 2, further comprising a spacer adjacent to the third conductive structure, wherein the direction is a first direction, the end is a first end, the spacer extends in a second direction substantially opposed to the first direction to a second end, and the first conductive structure extends in the second direction to a third end, the second end further along the second direction than the third end.

11. The device of claim 1, wherein the second conductive structure is at least partially enclosed in the dielectric region, and the dielectric region is at least partially enclosed in the first conductive structure.

12. A device, comprising:
a support structure;
a first nanoribbon and a second nanoribbon arranged in a stack over the support structure, the second nanoribbon extending in a first direction parallel to the first nanoribbon in the stack, the first nanoribbon having a first end along the first direction, the first nanoribbon having a first top extending in the first direction and a first bottom extending in the first direction; and
a capacitor structure adjacent to the first nanoribbon, the capacitor structure extending in the first direction from the first end of the first nanoribbon to a second end, wherein the capacitor structure has a second top extending in the first direction and a second bottom extending in the first direction, the first top and the second top are aligned, and the first bottom and the second bottom are aligned.

13. The device of claim 12, wherein the capacitor structure includes a first electrode structure having a first height between the second bottom and the second top, a second electrode structure nested within the first electrode structure, the second electrode structure having a second height that is less than the first height.

14. The device of claim 12, further comprising a gate region between the first nanoribbon and the second nanoribbon.

15. The device of claim 14, further comprising a spacer between the first nanoribbon and the second nanoribbon, the spacer adjacent to the gate region.

16. A method comprising:
providing a stack of first structures of a first material with second structures of a second material in between adjacent ones of the first structures, the stack having an end;
etching portions of the first structures from the end to form a plurality of cavities in the first structures at the end;
depositing a layer of a conductive material within the plurality of cavities.

17. The method of claim 16, further comprising depositing a layer of a dielectric material within the plurality of cavities over the conductive material.

18. The method of claim 17, further comprising depositing a second layer of the conductive material in the plurality of cavities over the dielectric material.

19. The method of claim 16, wherein the plurality of cavities is a first plurality of cavities, further comprising etching portions of the second structures from the end to form a second plurality of cavities in the second structures at the end, and depositing a spacer material in the second plurality of cavities in the second structures.

20. The method of claim 19, wherein a first cavity of the first plurality of cavities extends a first distance from the end into one of the first structures, a second cavity of the second plurality of cavities extends a second distance from the end into one of the second structures, and the second distance is greater than the first distance.
